(19) United States
(12) Patent Application Publication
(10) Pub. No.: US 2006/0289886 A1
(43) Pub. Date: Dec. 28, 2006

(54) Semiconductor light emitting device

(75) Inventor: Takayuki Sakai, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/262,891

(22) Filed: Nov. 1, 2005

(30) Foreign Application Priority Data
Jun. 24, 2005 (JP) 2005-184533

(51) Int. Cl. H01L 33/00

(52) U.S. Cl. 257/98

(57) ABSTRACT

A semiconductor light emitting device comprises: a semiconductor multilayer structure including a light emitting layer, a first semiconductor layer and a second semiconductor layer; a first electrode that forms ohmic contact with the first semiconductor layer in the semiconductor multilayer structure; a second electrode that forms ohmic contact with the second semiconductor layer in the semiconductor multilayer structure; and a light reflector, provided adjacent to the second electrode, configured to reflect at least part of emitted light from the light emitting layer. The second electrode has a plurality of regions having a width being no more than half an in-medium wavelength of the emitted light from the light emitting layer that propagates in the second semiconductor layer.

### CROSS-REFERENCE TO RELATED APPLICATIONS

This application is based upon and claims the benefit of priority from the prior Japanese Patent Application No. 2005-184533, filed on Jun. 24, 2005; the entire contents of which are incorporated herein by reference.

### BACKGROUND OF THE INVENTION

1. Field of the Invention

This invention relates to a semiconductor light emitting device, and more particularly to a semiconductor light emitting device with improved external light extraction efficiency.

2. Background Art

There is a continuing demand for semiconductor light emitting devices with high brightness and high external extraction efficiency for use in backlights of liquid crystal displays, push button lamps of mobile phones, car dashboard displays, and traffic lights. In these applications, a semiconductor light emitting device such as LED (light emitting diode) is mounted within a package, which is filled with sealing resin so as to cover the semiconductor light emitting device.

The semiconductor light emitting device has a light emitting layer, which is appropriately made of compound semiconductor such as GaN, AlGaAs, AlGaP, GaP, and InGaAlP corresponding to the wavelength range from ultraviolet to infrared. In order to form ohmic contact for this semiconductor layer, the material and concentration of an electrode and a semiconductor contact layer may be selected. In addition, a light reflector for reflecting light is provided on the opposite side of the light extraction side to improve external light extraction efficiency (see, e.g., Japanese Laid-Open Patent Application 2004-95941).

Typically, a metal electrode and a semiconductor contact layer are heat treated at 250 to 450° C., for example, to form an alloy layer, thereby reducing contact resistance. However, the alloy layer formed in this manner causes some loss due to light absorption, and light scattering. That is, light absorption loss and scattering in the alloy layer makes it difficult to achieve higher external light extraction efficiency. As a result, it is difficult to further enhance the brightness of semiconductor light emitting devices.

### SUMMARY OF THE INVENTION

According to an aspect of the invention, there is provided a semiconductor light emitting device comprising:

a semiconductor multilayer structure including a light emitting layer, a first semiconductor layer and a second semiconductor layer;

a first electrode that forms ohmic contact with the first semiconductor layer in the semiconductor multilayer structure;

a second electrode that forms ohmic contact with the second semiconductor layer in the semiconductor multilayer structure; and

a light reflector, provided adjacent to the second electrode, configured to reflect at least part of emitted light from the light emitting layer,

the second electrode having a plurality of regions having a width being no more than half an in-medium wavelength of the emitted light from the light emitting layer that propagates in the second semiconductor layer.

According to other aspect of the invention, there is provided a semiconductor light emitting device comprising:

a semiconductor multilayer structure including a double heterojunction, a first semiconductor layer and a second semiconductor layer;

a first electrode that forms ohmic contact with the first semiconductor layer in the semiconductor multilayer structure;

a second electrode that forms ohmic contact with the second semiconductor layer in the semiconductor multilayer structure; and

a first grating region provided in a first medium between the double heterojunction and the first electrode and including a first grating,

the first grating being formed by periodically arranging heterogeneous material in the first medium,

the heterogeneous material having a smaller refractive index than the first medium, and

the first grating having a pitch that is no more than an in-medium wavelength of emitted light from the double heterojunction that propagates in the first medium.

According to other aspect of the invention, there is provided

a semiconductor light emitting device comprising:

a semiconductor multilayer structure including a light emitting layer, a first semiconductor layer and a second semiconductor layer;

a first electrode that forms ohmic contact with the first semiconductor layer in the semiconductor multilayer structure;

a second electrode that forms ohmic contact with the second semiconductor layer in the semiconductor multilayer structure; and

a first grating region provided in a first medium between the light emitting layer and the first electrode and including a first grating,

the first grating having a pitch that is no more than an in-medium wavelength of emitted light from the light emitting layer that propagates in the first medium and that is no less than an in-medium wavelength of the emitted light in the first grating region.

### BRIEF DESCRIPTION OF THE DRAWINGS

FIG. 1 is a cross-sectional view that schematically shows a semiconductor light emitting device according to a first embodiment of the invention;

FIG. 2 is an enlarged schematic cross-sectional view of a surface region 345 of the semiconductor light emitting device indicated by a dashed line in FIG. 1;

FIG. 3 is a schematic view that partially illustrates the planar structure of the semiconductor light emitting device of the first embodiment;

FIG. 4 is a schematic view showing a first variation of the planar structure of a p-side electrode 340 of the semiconductor light emitting device of the first embodiment;

FIG. 5 is a schematic view showing a second variation of the planar structure of a p-side electrode 340 of the semiconductor light emitting device of the first embodiment;

FIG. 6 is a schematic cross-sectional view showing a variation in which the light reflector 350 has a larger film thickness than the p-side electrode 340;

FIG. 7 is a schematic plan view of the variation shown in FIG. 6;

FIG. 8 is a cross-sectional view that schematically shows a semiconductor light emitting device according to a second embodiment of the invention;

FIG. 9 is an enlarged cross-sectional view of a surface region 347 of the semiconductor light emitting device shown in FIG. 8;

FIG. 10 is a cross-sectional view that schematically shows a semiconductor light emitting device according to a third embodiment of the invention;

FIG. 11 is a schematic cross-sectional view of a semiconductor light emitting device according to a fourth embodiment of the invention;

FIG. 12 is an enlarged schematic cross-sectional view that partially shows a grating region 349;

FIG. 13 is a schematic cross-sectional view showing a semiconductor light emitting device according to a fifth embodiment of the invention;

FIG. 14 is an enlarged cross-sectional view of a grating region 485; and

FIG. 15 is an enlarged cross-sectional view of a grating region 495.

### DETAILED DESCRIPTION OF THE INVENTION

Embodiments of the invention will now be described with reference to the drawings.

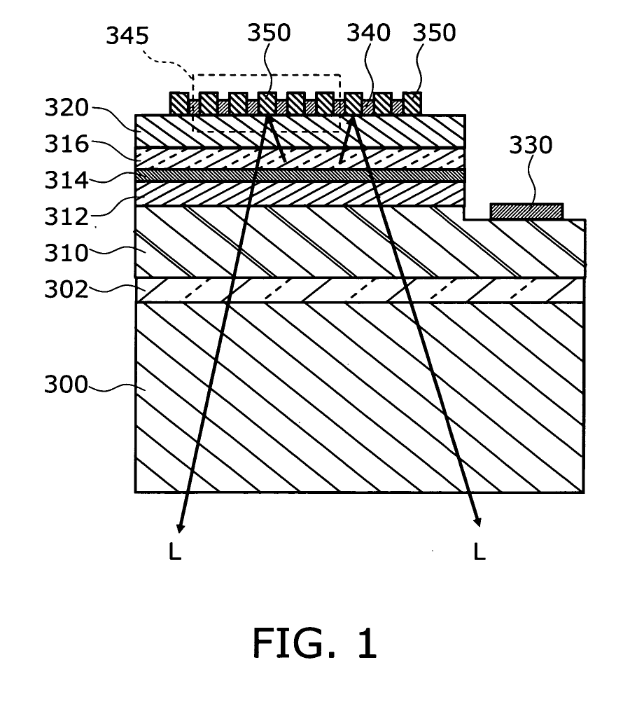

FIG. 1 is a cross-sectional view that schematically shows a semiconductor light emitting device according to a first embodiment of the invention.

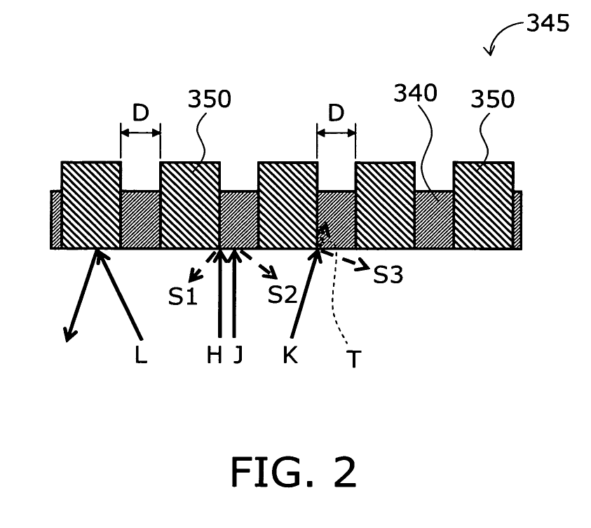

FIG. 2 is an enlarged schematic cross-sectional view of a surface region 345 of the semiconductor light emitting device indicated by a dashed line in FIG. 1.

The semiconductor light emitting device of this embodiment has a structure comprising a substrate 300 on which a GaN buffer layer 302, an n-type GaN layer 310, an n-type GaN guide layer 312, an active layer 314, a p-type GaN guide layer 316, and a p-type GaN layer 320 are provided in this order. The substrate 300 is made of sapphire, for example. The active layer 314 may comprise, for example, a MQW (Multi-Quantum Well) structure of In_{0.15}Ga_{0.85}N/In_{0.02}Ga_{0.98}N, and emit blue light, for example. An n-side electrode 330 is formed on the n-type GaN layer 310.

A p-side electrode 340 is interleaved with a light reflector 350 on the upper surface of the p-type GaN layer 320. The p-side electrode 340 is formed from material that forms an alloy layer with the GaN layer 320. The light reflector 350 is formed from material that does not form an alloy layer with the GaN layer 320. Note that the semiconductor light emitting device illustrated in FIG. 1 has the so-called “flip-chip structure”. At the time of packaging, therefore, the p-side electrode 340 side is bonded to a package, and light emitted from the active layer 314 is extracted via the substrate 300.

The p-side electrode 340 may be made of AuZn/Mo/Au or Ti/Pt/Au. The n-side electrode 330 may be made of AuGe/Mo/Au or Ti/Pt/Au. The light reflector 350 may be made of Au-based or Al-based metal film.

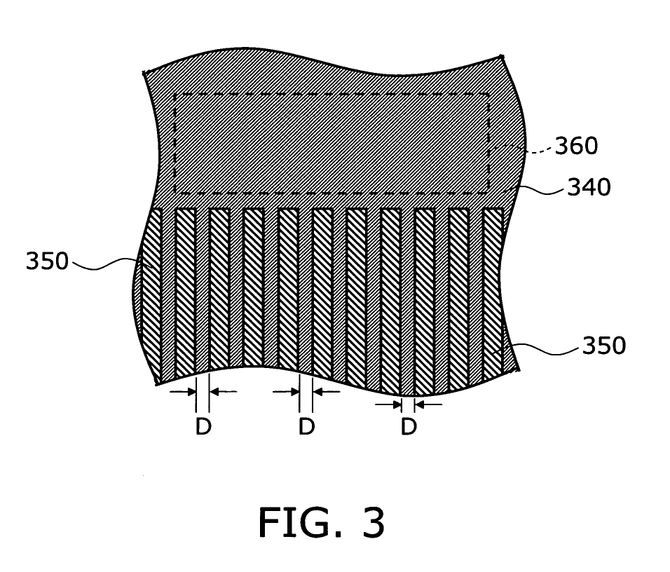

FIG. 3 is a schematic view that partially illustrates the planar structure of the semiconductor light emitting device of this embodiment.

In this example, the p-side electrode 340 is formed in a striped pattern having a width of D. The width D is set to be no more than half the in-medium wavelength (free space wavelength/medium refractive index) of emitted light of the semiconductor light emitting device in the medium adjacent to the electrode 340. For example, if the emitted light wavelength is 400 nm and the refractive index of the p-type GaN layer 320 is 2.67, then the in-medium wavelength is about 150 nm. In this case, therefore, the electrode width D should be 75 nm or less. In the case of wire bonding to the lead of a package rather than flip-chip bonding, the electrode 340 may be expanded as illustrated in FIG. 3 to form a bonding pad section 360. Alternatively, when the light reflector 350 is made of metal, the light reflector 350 may be expanded to form a bonding pad section 360, since the p-side electrode 340 is electrically connected to the light reflector 350.

The reason that the width D of the p-side electrode 340 is set to be no more than half the wavelength is now described.

When an agent such as the p-side electrode 340 is sufficiently larger than the wavelength of light, the light is treated as a light flux that travels in a straight line, and the behavior of light is described by geometrical optics including Snell's law. However, when the size of the agent is comparable to the wavelength of light, the light increases its wave nature and causes phenomena that cannot be described by geometrical optics. Light is “bent” because of its wave nature including diffraction and scattering. The wave nature manifests itself more prominently as the size of the agent gets smaller than the wavelength. In this region, it is impossible to exactly calculate the diffraction phenomenon based on electromagnetism.

Referring to FIGS. 1 and 2, light paths in the semiconductor light emitting device of this embodiment are described. Among the light beams directed upward from the active layer 314, many of the light beams L incident on the light reflector 350 are reflected nearly in accordance with geometrical optics. In this case, light is reflected at high reflectance because no alloy layer is formed between the light reflector 350 and the GaN layer 320.

On the other hand, part of light T incident on the p-side electrode 340 is absorbed by the alloy layer formed in the vicinity of the p-side electrode 340, which leads to some loss. However, since the width D of the electrode 340 is smaller than half the wavelength, light H, J, K being about to enter the electrode 340 follows wave optics including scattering and diffraction. This results in light S1, S2, S3 being scattered at the interface between the p-side electrode 340 and the p-type GaN layer 320 without being absorbed in the alloy layer. In general, as the width D of the p-side electrode 340 becomes smaller as compared to the wavelength, the wave nature of light is enhanced to increase scattered light components, thereby increasing the reflectance.

For example, when the width D of the p-side electrode 340 is a quarter of the wavelength and the area occupancy of the light reflector 350 is 70%, the light reflectance of about 85% is obtained. That is, a reflectance can be achieved that is about 15% higher than the nominal area occupancy of the light reflector 350. If the width D of the p-side electrode 340 is even smaller, then scattering is increased and thus the reflectance can be enhanced.

On the other hand, carriers are injected into and emitted from the semiconductor layer via the p-side electrode 340 even if the width D of the electrode 340 is small. That is, according to this embodiment, light reflection at the p-side electrode 340 can be enhanced without compromising the electric operation of the LED. This results in reducing loss of light in the alloy layer formed in the vicinity of the electrode, and thus the external light extraction efficiency can be improved.

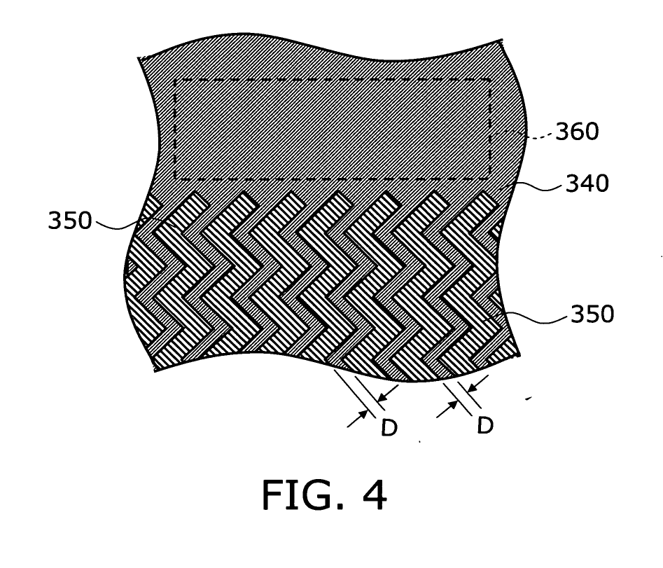

FIG. 4 is a schematic view showing a first variation of the planar structure of a p-side electrode 340 of the semiconductor light emitting device of this embodiment.

More specifically, the p-side electrode 340 in this variation is formed in a zigzag and striped pattern. In this variation again, the width D of the p-side electrode 340 is set to be no more than half the wavelength. This can facilitate reflection and scattering of light at the electrode 340, and reduce loss of light by the alloy layer.

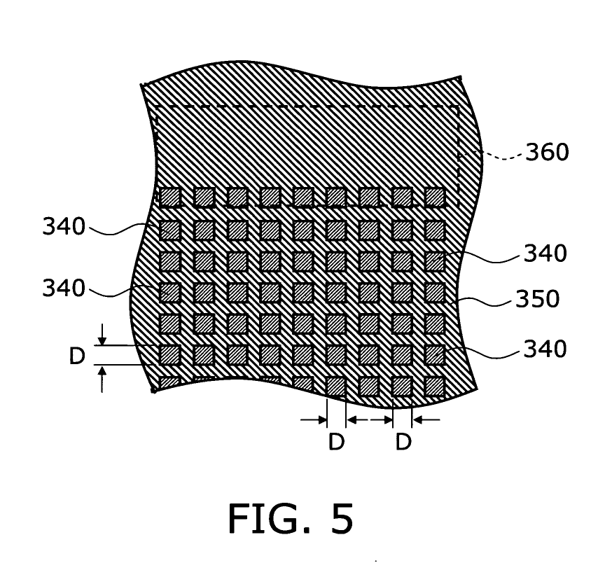

FIG. 5 is a schematic view showing a second variation of the planar structure of a p-side electrode 340 of the semiconductor light emitting device of this embodiment.

More specifically, the p-side electrode 340 in this variation is formed in an island-like pattern composed of a plurality of divided subregions. Each of the subregions is shaped as a square (or whatever other shape) measuring no more than half the wavelength per side. This can increase scattering and enhance the reflectance.

In the case of wire bonding to the lead of a package rather than flip-chip bonding, the metal portion constituting the light reflector 350 may be expanded to provide a bonding pad section 360. This enables light to be reflected at high reflectance also below the bonding pad section 360.

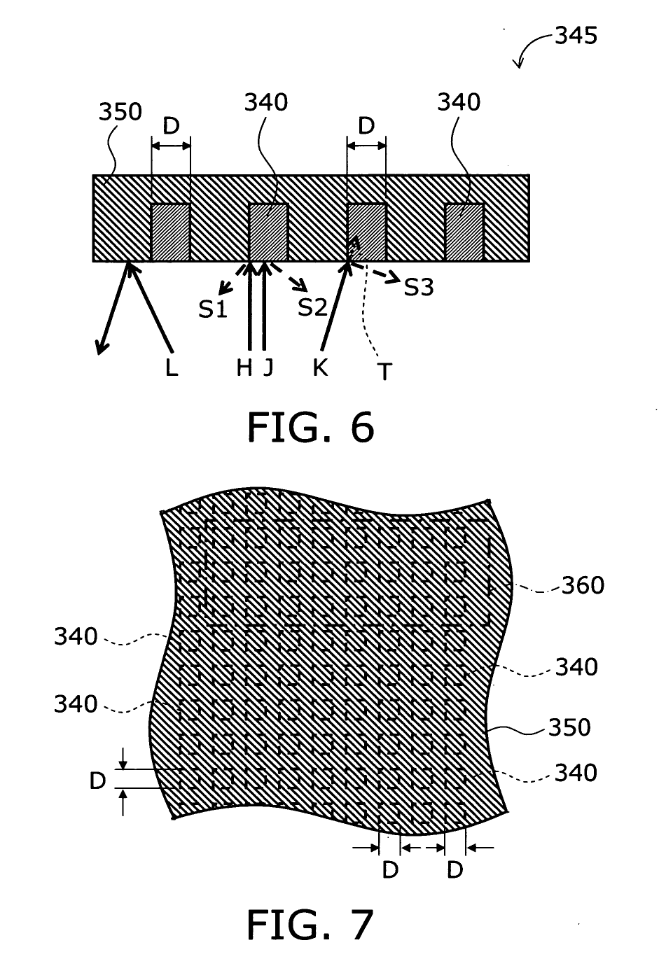

FIG. 6 is a schematic cross-sectional view showing a variation in which the light reflector 350 has a larger film thickness than the p-side electrode 340.

FIG. 7 is a schematic plan view of this variation.

In this variation again, the p-side electrode 340 is composed of a plurality of divided subregions. Each of the subregions is shaped as a square (or whatever other shape) measuring no more than half the wavelength per side. This can increase scattering and enhance the reflectance. Furthermore, the light reflector 350 can be made of metal to electrically interconnect the subregions of the p-side electrode 340 that are divided in an island-like pattern. The film thickness of the light reflector 350 can be made larger than that of the p-side electrode 340 so as to cover the p-side electrode 340, and thereby any portion on the light reflector 350 can also be used as a bonding pad section 360.

Next, a semiconductor light emitting device according to a second embodiment of the invention is described.

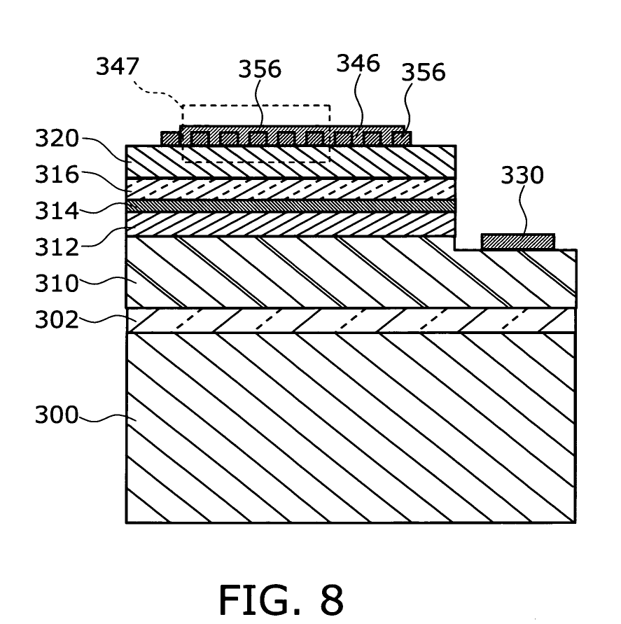

FIG. 8 is a cross-sectional view that schematically shows a semiconductor light emitting device according to this embodiment.

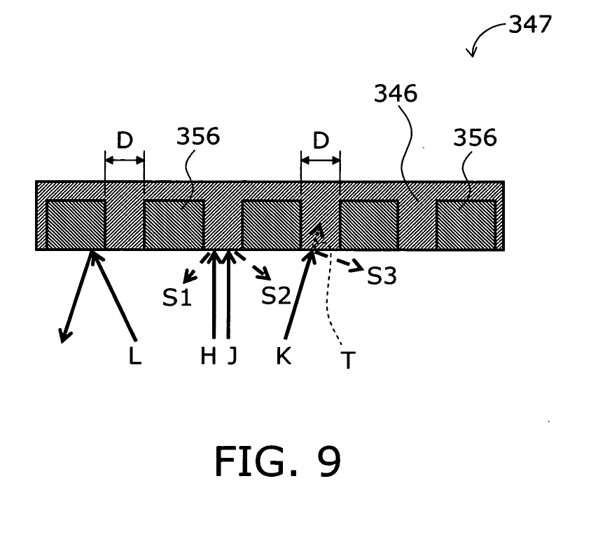

FIG. 9 is an enlarged cross-sectional view of a surface region 347 of the semiconductor light emitting device shown in FIG. 8. With regard to these figures, the elements similar to those described above with reference to FIGS. 1 to 7 are marked with the same reference numerals and will not be described in detail.

In this embodiment, a distributed Bragg reflector (DBR) 356 is provided instead of a light reflector made of metal material. The DBR can be formed by alternately laminating two kinds of thin films having different refractive indices. For example, five pairs (i.e., five cycles) of Al_{0.5}Ga_{0.5}N/GaN thin films yield a reflectance of about 50% at emission wavelengths in the range of 400 to 550 nm. The reflectance can be further enhanced by increasing the number of pairs.

In this embodiment again, the p-side electrode 346 between the adjacent regions of the distributed Bragg reflector 356 has a width D being no more than half the in-medium wavelength, as with the first embodiment.

The process of manufacturing a semiconductor light emitting device of this embodiment is as follows. After a laminated structure including a p-type GaN layer 320 is formed on a substrate 300, pairs of AlGaN/GaN thin films, for example, are laminated. The DBR layer is then patterned by photolithography, for example. A p-side electrode 346 is formed thereon. Besides the above laminated structure of semiconductor films, the distributed Bragg reflector 356 can also be achieved by laminating two or more kinds of dielectric films.

In this embodiment again, as with the first embodiment, among the light beams emitted from the active layer 314, the light beams directed toward the distributed Bragg reflector 356 are reflected. The reflected light is transmitted through the substrate 300 and extracted outside.

On the other hand, in the p-side electrode 346 having a width D of no more than half the wavelength, absorption and transmission do not occur, but only scattering occurs. More specifically, since the width D is no more than half the wavelength, incident light T cannot enter the alloy layer and therefore is reflected without absorption, which involves no loss. In contrast, light beams H, J, and K are scattered at the interface and extracted via the substrate 300, thereby contributing to improvement of external light extraction efficiency. The smaller the width D of the p-side electrode 346, the more occurrences of scattering, which can enhance reflection. On the other hand, since carriers can flow via the p-side electrode 346, the operation of the semiconductor light emitting device is not compromised.

Note that various examples described above with reference to FIGS. 3 to 7 can be applied to the planar configuration of the p-side electrode 346 and the distributed Bragg reflector 356.

Next, a semiconductor light emitting device according to a third embodiment of the invention is described.

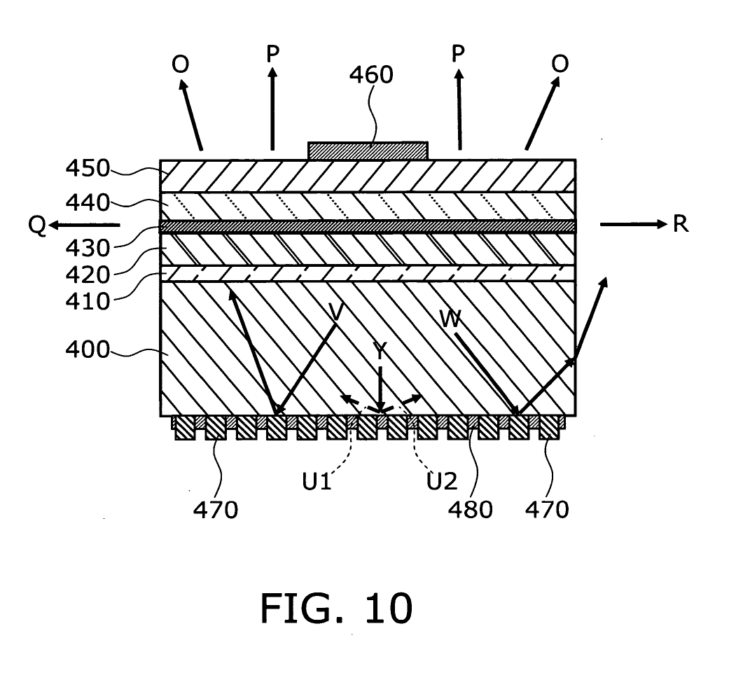

FIG. 10 is a cross-sectional view that schematically shows a semiconductor light emitting device according to a third embodiment of the invention.

The semiconductor light emitting device of this embodiment has a structure comprising a p-type GaP substrate 400 on which a p-type InGaAlP bonding layer 410, a p-type InGaAlP cladding layer 420, an InGaP/InGaAlP MQW active layer 430, an n-type InGaAlP cladding layer 440, and an n-type InGaAlP current diffusion layer 450 are laminated in this order. An n-side electrode 460 is formed on the upper surface of the current diffusion layer 450.

On the lower surface of the GaP substrate 400, as with the first embodiment, a light reflector 470 and a p-side electrode 480 made of metal material are provided. The width D of the p-side electrode 480 is set to be no more than half the in-medium wavelength. The active layer 430 emits light having a wavelength of 640 nm. Assuming that the refractive index of GaP is about 3.2, the in-medium wavelength is 200 nm. Therefore, the width D of the p-side electrode 480 should be 100 nm or less.

When the lower surface of the semiconductor light emitting device, that is, the p-side electrode 480 side is mounted on a packaging member, light beams O and P are emitted from the upper surface of the semiconductor light emitting device, and Q and R are emitted from the side surface thereof. On the other hand, light V emitted downward from the active layer 430 or reflected downward on the rear face of the electrode 460 is reflected by the light reflector 470 and can be externally extracted upward. Similarly, light W emitted downward from the active layer 430 or reflected downward on the rear face of the electrode 460 is reflected by the light reflector 470 and then emitted upward from the side surface. Furthermore, as described above with reference to FIG. 9, light Y directed toward the p-side electrode 480 is not subjected to absorption and transmission in the electrode 480 having a width D smaller than half the wavelength, and only generates scattered light U1, U2. As a result, the amount of light directed upward can be increased to improve external light extraction efficiency.

In this embodiment again, various configurations described above with reference to FIGS. 3 to 7 can be applied to the planar configuration of the light reflector 470 and the p-side electrode 480. In addition, the light reflector 470 may be a DBR as described above with reference to the second embodiment.

Next, a fourth embodiment of the invention is described.

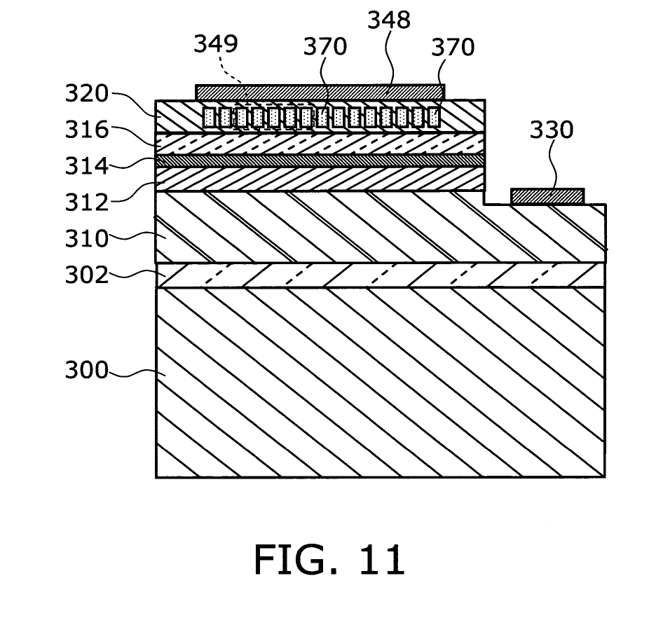

FIG. 11 is a schematic cross-sectional view of a semiconductor light emitting device according to a fourth embodiment of the invention. With regard to this figure, the elements similar to those described above with reference to FIGS. 1 to 9 are marked with the same reference numerals and will not be described in detail.

This embodiment comprises a double heterojunction composed of an n-type GaN guide layer 312, an active layer 314, and a p-type GaN guide layer 316. A p-side electrode 348 is provided on the double heterojunction via a p-type GaN layer 320. A grating 370 is provided within the p-type GaN layer 320. The grating 370 may be made of dielectric such as SiO₂ (having a refractive index of about 1.46) or semiconductor such as AlGaN, for example. Epitaxial growth is available for AlGaN or the like. The grating 370 has a pitch P1 being no more than the in-medium wavelength of emitted light of the semiconductor light emitting device. That is, in this example, the pitch P1 of the grating 370 is set to be no more than the in-medium wavelength in the GaN layer 320.

When semiconductor is used for the material of the grating 370, the p-type GaN layer 320 is epitaxially grown halfway. The material of the grating 370 is epitaxially grown thereon and patterned. The p-type GaN layer 320 can be epitaxially grown further thereon so as to bury the grating 370.

When dielectric such as SiO₂ is used for the material of the grating 370, it can be formed by “lateral epitaxy”, for example. More specifically, the p-type GaN layer 320 is epitaxially grown halfway. The material such as SiO₂ is deposited thereon and patterned to form a grating 370. When the p-type GaN layer 320 is epitaxially grown further thereon, epitaxial growth is initiated in the gaps of the grating 370. Once the gaps of the grating 370 are filled up, the epitaxial growth proceeds laterally over the grating 370. In this way, the p-type GaN layer 320 can be epitaxially grown so as to bury the grating 370 made of dielectric.

The behavior of light for the grating 370 having a pitch being no more than the in-medium wavelength is described. In general, if a grating has a pitch close to the wavelength of light, light is subjected to diffraction due to its wave nature instead of traveling in a straight line. A diffraction grating based on this phenomenon is used as a means for splitting light in an optical pickup. As the pitch or device feature of the grating gets smaller, the wave nature is even more prominent. In this situation, light behaves in accordance with wave optics rather than with geometrical optics. More specifically, when the pitch of the grating 370 is no more than the in-medium wavelength, the grating region 349 may be treated reasonably as a uniform medium having an optically averaged effective refractive index.

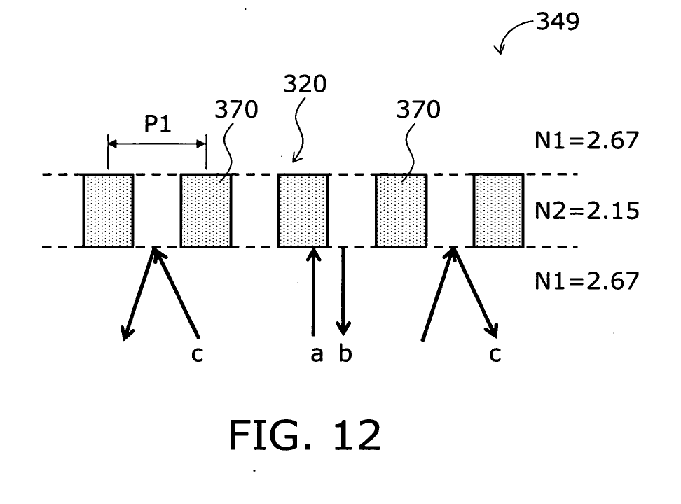

FIG. 12 is an enlarged schematic cross-sectional view that partially shows a grating region 349.

The refractive index N1 of the p-type GaN layer is about 2.67 and the refractive index of SiO₂ is about 1.46. The effective refractive index N2 of the grating region 349 is approximated by the optical average refractive index of these two if the pitch P1 of the grating is comparable to or less than the in-medium wavelength. In this case, if the wavelength of emitted light in vacuum is 400 nm, the in-medium wavelength in the p-type GaN layer is about 186 nm. Therefore, the pitch P1 of the grating is selected to be 186 nm or less.

The effective refractive index N2 of the grating region 349 in this case is given by the following formulas corresponding to the polarization direction of electric field of incident light:
Nh=((A×n₁²+B×n₂²)/(A+B))^{1/2}
Nv=((A+B)/(A/n₁²+B/n₂²))^{1/2}
where Nh is the effective refractive index of the grating region 349 for incident light whose electric field is horizontally polarized, and Nv is the effective refractive index of the grating region 349 for incident light whose electric field is vertically polarized. The volume ratio between the medium (GaN layer 320) and the grating 370 is assumed to be A:B, and n₁ and n₂ are the refractive indices of the medium (GaN layer 320) and the grating 370, respectively.

For typical non-polarized light, the effective refractive index of the grating region 349 can be approximated by the arithmetic mean of Nh and Nv.

Therefore, when the volume ratio between the GaN layer 320 and the grating 370 is 1:1, the effective refractive index N2 is equal to 2.15.

In this embodiment, light a vertically incident on the grating region 349 is reflected to produce the zeroth-order reflected light b. Since the refractive index of SiO₂ constituting the grating 370 is smaller than that of the medium (GaN layer 320) and thus the grating region 349 has a smaller effective refractive index than the adjacent GaN layer 320, light c obliquely incident on the grating region 349 is totally reflected at the interface therebetween to enhance the overall reflectance. This results in reducing loss in the alloy layer formed between the p-side electrode 348 and the p-type GaN layer 320 to increase optical output, and thus the external light extraction efficiency can be improved.

Note that carriers can pass through the gaps of the grating 370 and reach the electrode 348 without significantly affecting the current driving characteristics.

While the grating is spaced apart from the electrode in the fourth embodiment, the grating may be adjacent to the electrode.

Next, a semiconductor light emitting device according to a fifth embodiment of the invention is described.

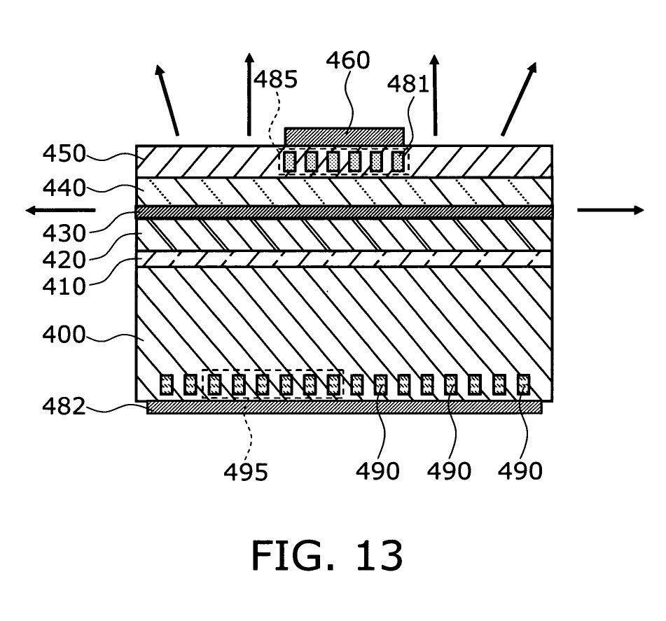

FIG. 13 is a schematic cross-sectional view showing a semiconductor light emitting device according to a fifth embodiment of the invention. With regard to this figure, the elements similar to those described above with reference to FIG. 10 are marked with the same reference numerals and will not be described in detail.

In this embodiment, a grating 481 having a pitch P2 of no more than the in-medium wavelength is formed within the n-type InGaAlP current diffusion layer 450 below the n-side electrode 460.

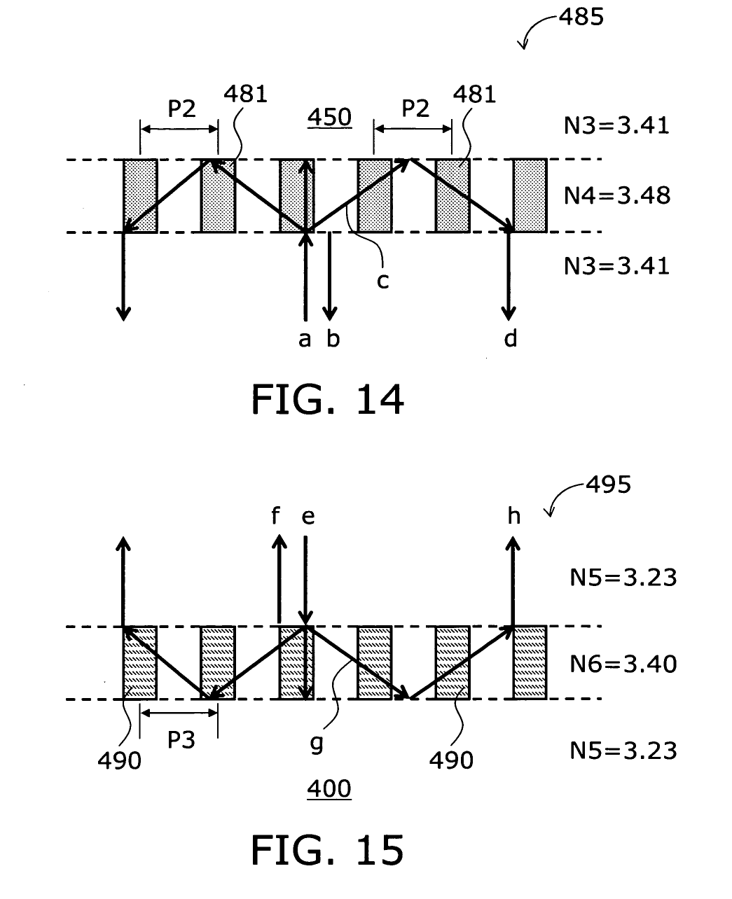

FIG. 14 is an enlarged cross-sectional view of a grating region 485.

The grating 481 may be made of ZnTe having a refractive index of about 3.56, for example. As described above with reference to the fourth embodiment, when the pitch P2 is comparable to or less than the in-medium wavelength (in this example, the n-type InGaAlP current diffusion layer 450 is the medium), the grating region 485 can be considered as a uniform medium having an optically averaged effective refractive index.

For example, when the emission wavelength in free space is 640 nm, the pitch P2 should be no more than 187.6 nm, which is the in-medium wavelength in InGaAlP.

In this case again, as described above with reference to the fourth embodiment, the arithmetic mean of the effective refractive indices Nh and Nv, with the volume ratio between the n-type InGaAlP current diffusion layer 450 and the grating (ZnTe) 481 taken into account, can be considered as the effective refractive index of the grating region 485. Therefore, when the volume ratio is 1:1, the effective refractive index N4 of the grating region 485 is equal to 3.48.

That is, the grating region 485 can be approximated as a region uniformly filled with the medium having the effective refractive index N4.

Furthermore, in this example, when the pitch P2 of the grating 481 is no less than the in-medium wavelength in the grating region 485, the grating 481 has a diffraction effect on light propagating in the grating region 485. More specifically, as shown in FIG. 14, light a incident on the grating region 485 is diffracted by the grating 481 in the grating region 485 to produce diffracted light c. For this to be achieved, the pitch P2 of the grating 481 should be set to no less than 183.9 nm (the wavelength within the grating region 485), for example, to 185 nm.

The diffracted light c thus produced is totally reflected at the interface and can be extracted as reflected light d as shown in FIG. 14 because, as described above, the effective refractive index N4 (3.48) in the grating region 485 is greater than the refractive index (3.41) of the InGaAlP current diffusion layer 450.

Furthermore, in this embodiment, another grating 490, which is an agent similar to the upper grating 481, is provided also in the lower part of the semiconductor multilayer structure. More specifically, a grating region 495 having a grating 490 within the p-type GaP substrate 400 is formed above the p-side electrode 482. The grating 490 may be formed from ZnTe, for example.

FIG. 15 is an enlarged cross-sectional view of the grating region 495.

In this case again, the pitch P3 of the grating 490 is set to be no more than 198.1 nm, which is the wavelength within the medium (which is GaP having a refractive index N5 of 3.23), and no less than 188.2 nm, which is the wavelength in the grating region 495. Thus, for example, the pitch P3 is set to 190 nm. The arithmetic mean of Nh and Nv, with the volume ratio between GaP and ZnTe taken into account, can be considered as the effective refractive index of the grating region 495. For example, when the volume ratio is 1:1, the effective refractive index N6 is equal to 3.4.

In this embodiment, light a, e vertically incident on the grating region 485, 495 is reflected to produce the zeroth-order reflected light b, f. The pitch P2, P3 of the grating 481, 490 is made greater than the wavelength within the grating region to produce a diffraction effect in the grating region 485, 495, respectively. That is, the light that has entered the grating region 485, 495 is diffracted to produce the first-order diffracted light c, g. Since the effective refractive index of the grating region 485, 495 is greater than that of the semiconductor layers located above and below, the first-order diffracted light c, g is totally reflected at the interface to become outgoing light d, h toward the incident side, which enhances the overall reflectance.

Alternatively, if the pitch P2, P3 of the grating 481, 490 is made equal to the wavelength within the grating region 485, 495 (183.9 and 188.2 nm, respectively), then resonant reflection occurs, which further enhances reflection.

The grating region 485, 495 thus provided in front of the electrode 460, 482 can reduce loss of light in the alloy layer of the electrode 460, 482. That is, external light extraction efficiency is improved. On the other hand, carriers can pass through the gaps of the grating 481, 490 without significantly affecting the current driving characteristics.

While the gratings are provided in front of the first and second electrodes in the fifth embodiment, the grating may be provided in front of only one of the electrodes.

Embodiments of the invention have been described with reference to examples. However, the invention is not limited to these examples.

For example, the invention is not limited to the use of GaN-based and InGaAlP-based compound semiconductors for the semiconductor multilayer structure. GaAlAs-based, ZnSe-based, and various other compound semiconductors may be used.

The light emitted from the semiconductor light emitting device is not limited to visible light, but may include ultraviolet or infrared light. For example, ultraviolet or blue light can be combined with phosphors dispersed in sealing resin to perform wavelength conversion for obtaining white light.

Any configuration, size, material, and arrangement of various elements including the substrate, semiconductor layers, and electrodes composing the semiconductor light emitting device that are adapted by those skilled in the art are also encompassed within the scope of the invention as long as they include the features of the invention.

Note that the “GaN-based” compound semiconductor used herein includes semiconductors having any composition represented by the chemical formula InₓAl_{y}Ga_{1-x-y}N (0≦x≦1, 0≦y≦1, x+y≦1) where the composition ratios x and y are varied in the respective ranges. Furthermore, the “GaN-based” compound semiconductor also includes those further containing any group V elements other than N (nitrogen), and those further containing any of various dopants added for controlling conductivity types.

In addition, the “InGaAlP-based” compound semiconductor used herein includes semiconductors having any composition represented by the chemical formula InₓGa_{y}Al_{1-x-y}P (0≦x≦1, 0≦y≦1, x+y≦1) where the composition ratios x and y are varied in the respective ranges. Furthermore, the “InGaAlP-based” compound semiconductor also includes those further containing any group V elements other than P (phosphorus), and those further containing any of various dopants added for controlling conductivity types.

While the present invention has been disclosed in terms of the embodiment in order to facilitate better understanding thereof, it should be appreciated that the invention can be embodied in various ways without departing from the principle of the invention. Therefore, the invention should be understood to include all possible embodiments and modification to the shown embodiments which can be embodied without departing from the principle of the invention as set forth in the appended claims.

1. A semiconductor light emitting device comprising:
a semiconductor multilayer structure including a light emitting layer, a first semiconductor layer and a second semiconductor layer;
a first electrode that forms ohmic contact with the first semiconductor layer in the semiconductor multilayer structure;
a second electrode that forms ohmic contact with the second semiconductor layer in the semiconductor multilayer structure; and
a light reflector, provided adjacent to the second electrode, configured to reflect at least part of emitted light from the light emitting layer,
the second electrode having a plurality of regions having a width being no more than half an in-medium wavelength of the emitted light from the light emitting layer that propagates in the second semiconductor layer.

2. A semiconductor light emitting device as claimed in claim 1, wherein the light reflector is provided between adjacent regions of the plurality of regions.

3. A semiconductor light emitting device as claimed in claim 1, wherein the light reflector comprises metal.

4. A semiconductor light emitting device as claimed in claim 1, wherein the light reflector comprises a distributed Bragg reflector.

5. A semiconductor light emitting device as claimed in claim 1, wherein each of the plurality of regions is formed in a stripe configuration.

6. A semiconductor light emitting device as claimed in claim 1, wherein each of the plurality of regions is formed in a zigzag stripe configuration.

7. A semiconductor light emitting device as claimed in claim 1, wherein each of the plurality of regions is formed in an island-like configuration.

8. A semiconductor light emitting device as claimed in claim 1, wherein the second electrode has a bonding section to which the plurality of regions are commonly connected and that is wider than the plurality of regions.

9. A semiconductor light emitting device as claimed in claim 1, wherein the plurality of regions are electrically connected via the light reflector.

10. A semiconductor light emitting device as claimed in claim 9, wherein the light reflector is formed thick enough to cover the second electrode.

11. A semiconductor light emitting device as claimed in claim 1, wherein the light emitting layer comprises GaN-based compound semiconductor.

12. A semiconductor light emitting device as claimed in claim 1, wherein
the semiconductor multilayer structure comprises InGaAlP-based compound semiconductor, and
the second semiconductor layer is a GaP substrate.

13. A semiconductor light emitting device comprising:
a semiconductor multilayer structure including a double heterojunction, a first semiconductor layer and a second semiconductor layer;
a first electrode that forms ohmic contact with the first semiconductor layer in the semiconductor multilayer structure;
a second electrode that forms ohmic contact with the second semiconductor layer in the semiconductor multilayer structure; and
a first grating region provided in a first medium between the double heterojunction and the first electrode and including a first grating,
the first grating being formed by periodically arranging heterogeneous material in the first medium,
the heterogeneous material having a smaller refractive index than the first medium, and
the first grating having a pitch that is no more than an in-medium wavelength of emitted light from the double heterojunction that propagates in the first medium.

14. A semiconductor light emitting device as claimed in claim 13, wherein the first medium is the first semiconductor layer.

15. A semiconductor light emitting device comprising:
a semiconductor multilayer structure including a light emitting layer, a first semiconductor layer and a second semiconductor layer;
a first electrode that forms ohmic contact with the first semiconductor layer in the semiconductor multilayer structure;
a second electrode that forms ohmic contact with the second semiconductor layer in the semiconductor multilayer structure; and
a first grating region provided in a first medium between the light emitting layer and the first electrode and including a first grating,
the first grating having a pitch that is no more than an in-medium wavelength of emitted light from the light emitting layer that propagates in the first medium and that is no less than an in-medium wavelength of the emitted light in the first grating region.

16. A semiconductor light emitting device as claimed in claim 15, wherein the first grating is formed by periodically arranging heterogeneous material in the first medium, the heterogeneous material having a greater refractive index than the first medium.

17. A semiconductor light emitting device as claimed in claim 15, wherein the first medium is the first semiconductor layer.

18. A semiconductor light emitting device as claimed in claim 15, further comprising:
a second grating region provided in a second medium between the light emitting layer and the second electrode and including a second grating, wherein
the second grating has a pitch that is no more than an in-medium wavelength of emitted light from the light emitting layer that propagates in the second medium and that is no less than an in-medium wavelength of the emitted light in the second grating region.

19. A semiconductor light emitting device as claimed in claim 18, wherein the second grating is formed by periodically arranging heterogeneous material in the second medium, the heterogeneous material having a greater refractive index than the second medium.

20. A semiconductor light emitting device as claimed in claim 18, wherein the second medium is the second semiconductor layer.
